(19) United States
(12) Patent Application Publication
(10) Pub. No.: US 2014/0191748 A1
(43) Pub. Date: Jul. 10, 2014

(54) SIGNAL TEST DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventors: SONG MA, Shenzhen (CN); WU ZHOU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/951,510

(22) Filed: Jul. 26, 2013

(30) Foreign Application Priority Data
Jan. 8, 2013 (CN) 2013100060559

(51) Int. Cl. G01R 1/067

(52) U.S. Cl. CPC G01R 1/067
USPC 324/149

(57) ABSTRACT

A signal test device includes a probe column, a probe pin, and a cable. The probe pin includes a first end contacted with an electronic device and a second end located inside the probe column. A first conductive piece set in the probe column is connected to a signal line of the cable. A second conductive piece is set apart from and below the first conductive piece in the probe column, and is connected to the second end of the probe pin. When the first end of the probe pin is pressed to the electronic device, the probe pin moves into the probe column and the second conductive piece contacts the first conductive piece. When the second conductive piece contacts with the first conductive piece, a snapshot of a waveform of the electronic device is captured and shown on the oscilloscope.

### BACKGROUND

1. Technical Field

The present disclosure relates to a signal test device.

2. Description of Related Art

Signals of electronic devices can be tested using an oscilloscope or oscillograph. The test devices usually include a plurality of probes, each of which is used to contact a device to be tested. Running the tests can be difficult because buttons and/or dials may need to be used on the test device while at the same time manually positioning the probes to be in contact with one or more devices to be tested.

Therefore, there is need for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a schematic view of an embodiment of a signal test device.

FIG. 2 is a schematic view of a probe column, a probe pin, a first conductive piece, and a second conductive piece of the signal test device of FIG. 1.

FIG. 3 is a block diagram of the signal test device of FIG. 1.

### DETAILED DESCRIPTION

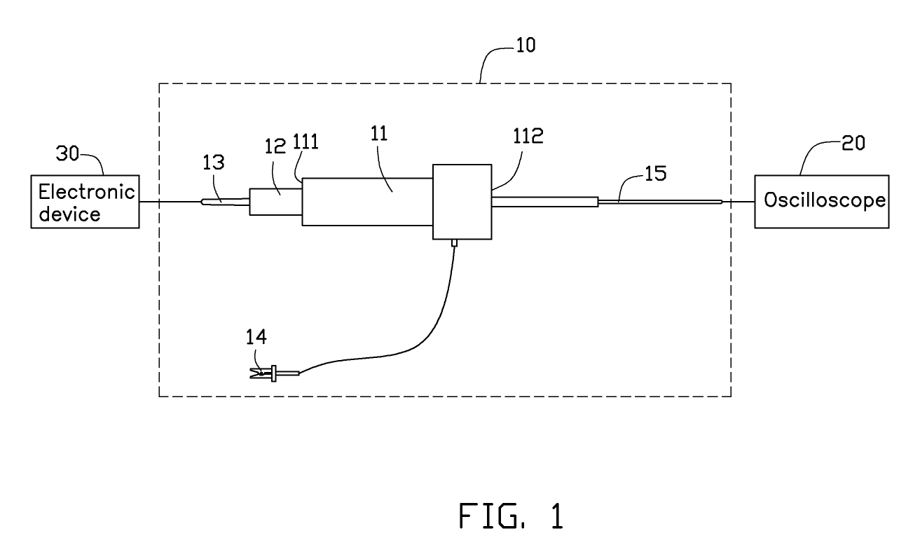

FIGS. 1-3 show an embodiment of a signal test device 10. The signal test device 10 is used to test a signal of an electronic device 30, in cooperation with an oscilloscope 20. The signal test device 10 includes a probe body 11, a hollow probe column 12 extending from a first end 111 of the probe body 11, a probe pin 13, a ground terminal 14, and a cable 15. A first end of the cable 15 is set in the probe body 11. A second end of the cable 15 extends out of the probe body 11 from a second end 112 of the probe body 111 opposite to the first end 111. The probe column 12 includes a first conductive piece 123 and a second conductive piece 124 both set inside the probe column 12. The cable 15 includes a signal line 150 electrically connected between the first conductive piece 123 and the oscilloscope 20, and a ground line 151 connected between the ground terminal 14 and the oscilloscope 20.

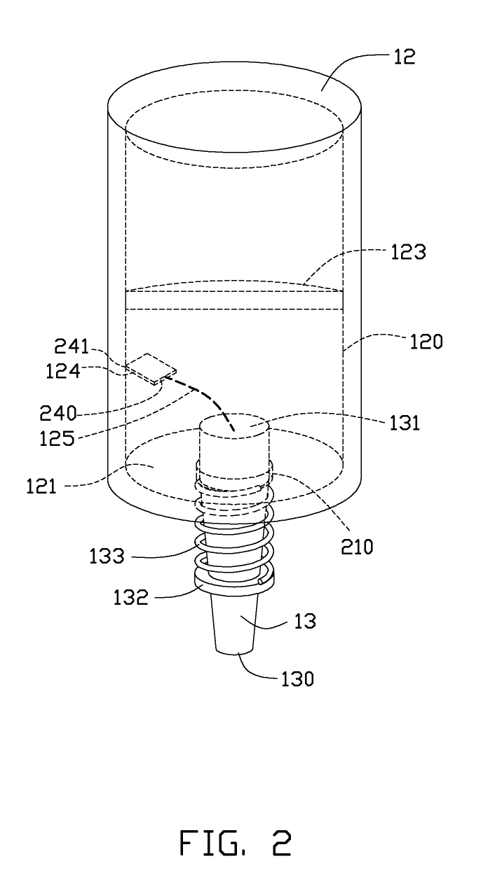

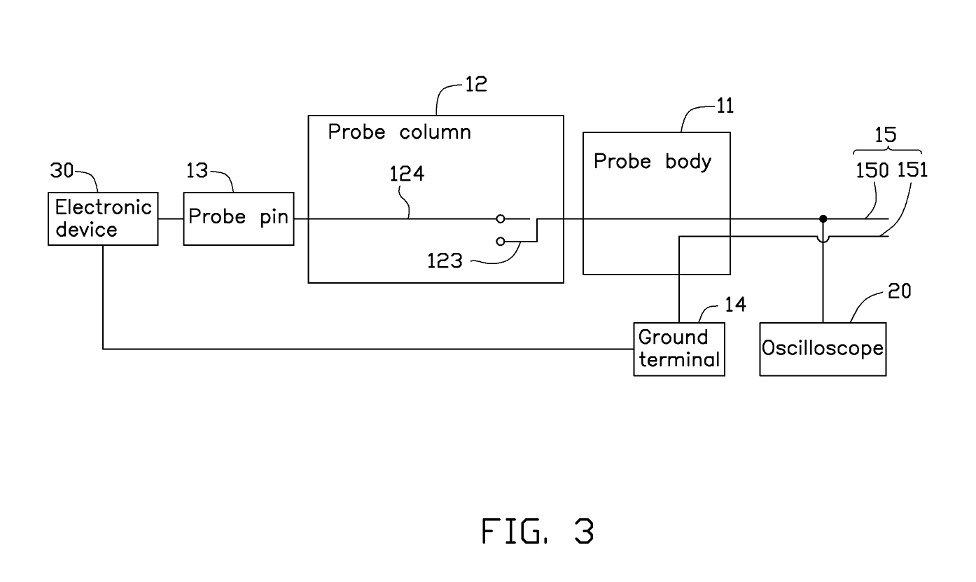

FIGS. 2 and 3 show the probe column 12 including an inner wall 120 and a bottom wall 121 perpendicularly connected to a bottom end of the inner wall 120. The bottom wall 121 defines a through hole 210. The probe pin 13 is frustum shaped, and includes a first end 130 and a second end 131 opposite to the first end 130. The first end 130 is used to contact with the object 30 to be tested. The probe pin 13 extends through the through hole 210, with the first end 130 located outside the probe column 12, and the second end 131 located in the probe column 12, and the probe pin 13 can move in the through hole 210 along an axis of the probe pin 13. A diameter of the through hole 210 is greater than a diameter of the first end 130 of the probe pin 13, and is less than a diameter of the second end 131 of the probe pin 13. Thereby, the probe pin 13 cannot disengage from the probe column 12 through the through hole 210 of the bottom wall 121.

An annular projection 132 extends from a circumference of the probe pin 13 and is located outside the probe column 12. A spring 133 is fitted about the probe pin 13 between the projection 132 and the bottom wall 121 of the probe column 12.

The first conductive piece 123 is mounted on the inner wall 120 of the probe column 12. The second conductive piece 124 is apart from and below the first conductive piece 123 in the probe column 12. A first end 240 of the second conductive piece 124 is connected to the second end 131 of the probe pin 13 through a connection rod 125. A second end 241 of the second conductive piece 124 is slidably contacted with the inner wall 120 of the probe column 12. The conductive piece 124 can move along the inner wall 120 with movement of the probe pin 13.

In use, the ground terminal 14 is electrically connected to a ground terminal of the electronic device 30. When the first end 130 of the probe pin 13 is contacted to a signal terminal of the electronic device 30, and the probe pin 13 is withdrawn into the probe column 12 to make the second conductive piece 124 contact the first conductive piece 123, a live waveform of a signal of the electronic device 30 is shown on the oscilloscope 20.

When the first end 130 of the probe pin 13 is pressed to the signal terminal of the electronic device 30, a portion of the probe pin 13 moves into the probe column 12 compressing the spring 133. The second conductive piece 124 is pushed by the connection rod 125 along the inner wall 120 to contact the first conductive piece 123. When the second conductive piece 124 contacts the first conductive piece 123, a snapshot of the waveform of the electronic device 30 is captured and shown by the oscilloscope 20, due to the first conductive piece 123 being electrically connected to the waveform capture controller of the oscilloscope 20 through the cable 15.

When the pressure applied on the signal terminal of the electronic device 30 by the probe pin 13 is removed, the spring 133 restores to extend the probe pin 13 back out the probe column 12 opening the connection between the second conductive piece 124 and the first conductive piece 123. Using the present signal test device allows a user to control capturing stills of a live waveform by manipulation of the probes they are holding rather than having to reach for buttons and/or dials on the oscilloscope.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A signal test device for an electronic device, comprising:
a hollow probe column comprising a bottom wall;
a first conductive piece mounted in the probe column;
a probe pin slidably mounted to the bottom wall of the probe column, and comprising a first end located outside the probe column and configured to contact with a signal terminal of the electronic device, and a second end located inside the probe column;
a second conductive piece electrically connected to the second end of the probe pin and movable with the probe pin;
a cable comprising a signal line connected between an oscilloscope and the first conductive piece, and a ground line; and
a ground terminal to contact with a ground end of the electronic device, wherein the ground line of the cable is connected between the oscilloscope and the ground terminal;
wherein when the first end of the probe pin is pressed to the signal terminal of the electronic device, and the ground terminal is contacted with the ground end of the electronic device, the probe pin moves into the probe column, the second conductive piece contacts the first conductive piece; when the second conductive piece contacts the first conductive piece, a snapshot of a waveform of the electronic device is captured and shown on the oscilloscope.

2. The signal test device of claim 1, wherein the probe further comprises an inner wall, the bottom wall is perpendicularly connected to a bottom end of the inner wall; the bottom wall defines a through hole; the probe pin is frustum shaped, and extends through the through hole; a diameter of the through hole is greater than a diameter of the first end of the probe pin, and is less than a diameter of the second end of the probe pin.

3. The signal test device of claim 2, further comprising a spring, wherein a projection extends from a circumference of the probe pin and locates outside the probe column; the spring is fitted about the probe pin between the projection and the bottom wall of the probe column.

4. The signal test device of claim 3, wherein a first end of the second conductive piece is connected to the second end of the probe pin through a connection rod, a second end of the conductive piece slidably contacts with the inner wall of the probe column; when the probe pin moves into the probe column, the second conductive piece is pushed by the connection rod along the inner wall to contact the first conductive piece, and makes the second conductive piece contact the first conductive piece.
